(19) United States
(12) Patent Application Publication
(10) Pub. No.: US 2026/0147962 A1
(43) Pub. Date: May 28, 2026

(54) DATA PROCESSING SYSTEM, DATA PROCESSING METHOD, AND NON-TRANSITORY COMPUTER-READABLE MEDIUM

(71) Applicant: NEC Corporation, Tokyo (JP)

(72) Inventors: Akira MATSUKI, Tokyo (JP); Keisuke IKEDA, Tokyo (JP); Kenta SENZAKI, Tokyo (JP); Masahiro TANI, Tokyo (JP)

(73) Assignee: NEC Corporation, Tokyo (JP)

(21) Appl. No.: 19/385,413

(22) Filed: Nov. 11, 2025

(30) Foreign Application Priority Data
Nov. 25, 2024 (JP) 2024-204412

(51) Int. Cl. G06F 30/27; G06N 3/042

(52) U.S. Cl. CPC G06F 30/27; G06N 3/042

(57) ABSTRACT

A data processing system according to the present disclosure includes at least one memory storing instructions, and at least one processor configured to execute the instructions to arrange an agent in a multi-agent simulation, an environment of the simulation in which the agent is active, and a characteristic of the agent or the environment as nodes in a graph structure, and generate, as a scenario in the simulation, the graph structure in which a first node indicating the agent or a second node indicating the environment and a third node indicating the characteristic are connected.

### INCORPORATION BY REFERENCE

This application is based upon and claims the benefit of priority from Japanese patent application No. 2024-204412, filed on November 25, 2024, the disclosure of which is incorporated herein in its entirety by reference.

### TECHNICAL FIELD

The present disclosure relates to a data processing system, a data processing method, and a non-transitory computer-readable medium.

### BACKGROUND ART

In recent years, a technology related to scenario generation for executing simulation has been disclosed. For example, C. Chang, et al.,“ LLMScenario: Large Language Model Driven Scenario Generation,” IEEE Transactions on Systems, Man, Cybernetics: Systems, Vol. 54, Issue 11, November 2024, discloses a technology for generating a traffic scenario of a graph structure using a Large Language Model (LLM). In C. Chang, et al.,“ LLMScenario: Large Language Model Driven Scenario Generation,” IEEE Transactions on Systems, Man, Cybernetics: Systems, Vol. 54, Issue 11, November 2024, it is possible to extract vehicle data from open data accumulated as real data and generate a corner scenario, that is, a rare and dangerous scenario. The open data is, for example, a video of a drive recorder.

### SUMMARY

The scenario generated in C. Chang, et al.,“ LLMScenario: Large Language Model Driven Scenario Generation,” IEEE Transactions on Systems, Man, Cybernetics: Systems, Vol. 54, Issue 11, November 2024, is based on the positional relationship on the road of the vehicle and the pedestrian included in the open data. Therefore, in the technology according to C. Chang, et al.,“ LLMScenario: Large Language Model Driven Scenario Generation,” IEEE Transactions on Systems, Man, Cybernetics: Systems, Vol. 54, Issue 11, November 2024, it is not possible to generate a scenario based on information that is not disclosed as open data. Thus, the technology according to C. Chang, et al.,“ LLMScenario: Large Language Model Driven Scenario Generation,” IEEE Transactions on Systems, Man, Cybernetics: Systems, Vol. 54, Issue 11, November 2024, has a problem that a scenario with high comprehensiveness cannot be generated.

The present disclosure has been made to solve such a problem, and an example object thereof is to provide a data processing system, a data processing method, and a non-transitory computer-readable medium capable of generating a scenario with high comprehensiveness.

A data processing system according to an example aspect of the present disclosure includes at least one memory storing instructions, and at least one processor configured to execute the instructions to arrange an agent in a multi-agent simulation, an environment of the simulation in which the agent is active, and a characteristic of the agent or the environment as nodes in a graph structure, and generate, as a scenario in the simulation, the graph structure in which a first node indicating the agent or a second node indicating the environment and a third node indicating the characteristic are connected.

A data processing method according to an example aspect of the present disclosure includes, by a computer, arranging an agent in a multi-agent simulation, an environment of the simulation in which the agent is active, and a characteristic of the agent or the environment as nodes in a graph structure, and generating, as a scenario in the simulation, the graph structure in which a first node indicating the agent or a second node indicating the environment and a third node indicating the characteristic are connected.

A non-transitory computer-readable medium storing a program according to an example aspect of the present disclosure causes a computer to execute a step of arranging an agent in a multi-agent simulation, an environment of the simulation in which the agent is active, and a characteristic of the agent or the environment as nodes in a graph structure, and a step of generating, as a scenario in the simulation, the graph structure in which a first node indicating the agent or a second node indicating the environment and a third node indicating the characteristic are connected.

According to the present disclosure, it is possible to provide a data processing system, a data processing method, and a non-transitory computer-readable medium capable of generating a scenario with high comprehensiveness.

### BRIEF DESCRIPTION OF DRAWINGS

The above and other aspects, features, and advantages of the present disclosure will become more apparent from the following description of certain example embodiments in a case where taken in conjunction with the accompanying drawings, in which:

FIG. 1 is a block diagram illustrating a configuration of a data processing system according to the present disclosure;

FIG. 2 is an example of a graph structure generated by a scenario generation unit;

FIG. 3 is a flowchart illustrating an example of a processing operation of the data processing system;

FIG. 4 is a block diagram illustrating a configuration of a data processing system according to the present disclosure;

FIG. 5 is a table illustrating statistical information of a connection frequency between the edge and the node;

FIG. 6 is a histogram illustrating statistical information of the connection frequency between the edge and the node;

FIG. 7 is a flowchart illustrating an example of a processing operation of the data processing system;

FIG. 8 is a flowchart illustrating an example of a flow in a case where the scenario generation unit generates a scenario based on the similarity;

FIG. 9 is a block diagram illustrating a configuration of a data processing system according to the present disclosure;

FIG. 10 is a flowchart illustrating an example of scenario generation processing in the data processing system;

FIG. 11 is a flowchart illustrating an example of scenario recording processing in the data processing system;

FIG. 12 is a flowchart illustrating an example of scenario generation processing in the data processing system;

FIG. 13A is a schematic diagram illustrating an example of a simulation result based on a scenario by the data processing system;

FIG. 13B is a schematic diagram illustrating an example of a simulation result based on a scenario by the data processing system;

FIG. 13C is a schematic diagram illustrating an example of a simulation result based on a scenario by the data processing system; and

FIG. 14 is a diagram illustrating a hardware configuration example of a data processing system according to the present disclosure.

### EXAMPLE EMBODIMENT

### First Example Embodiment

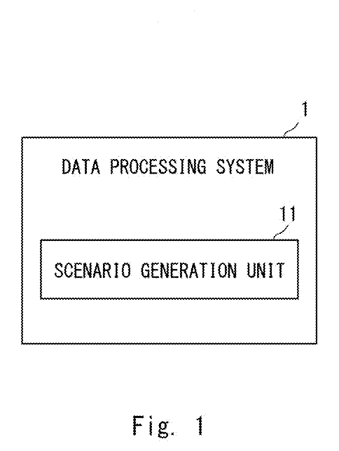

Hereinafter, a first example embodiment according to the present disclosure will be described with reference to the drawings. FIG. 1 is a block diagram illustrating a configuration of a data processing system 1 according to the present disclosure. The data processing system 1 is a system for generating a scenario for executing a multi-agent simulation. The multi-agent simulation is a simulation performed using a model in which a plurality of autonomous agents interact with each other. The multi-agent simulation simulates, for example, a people flow or a traffic flow. Here, the agent may be a person, an animal, an automobile driven by a person, an autonomous traveling robot, or a micro article such as pollen or bacteria. That is, the agent includes, in its scope, all objects in which individual characteristics and behaviors can be identified and designed. Hereinafter, the multi-agent simulation may be simply referred to as “simulation”. The data processing system 1 includes a scenario generation unit 11.

The scenario generation unit 11 arranges an agent, an environment, and characteristics of the agent or the environment in the multi-agent simulation as nodes in a graph structure, and generates a graph structure in which a node indicating the agent or a node indicating the environment and a node indicating the characteristics are connected as a scenario in the simulation. That is, the scenario generation unit 11 generates a scenario of a graph structure. In other words, the scenario generation unit 11 generates the graph structure as a scenario in the simulation. The graph structure is a data structure including a plurality of nodes (nodal points) and edges (sides) representing a relationship between the nodes. In the first example embodiment, generating a graph structure and generating a scenario have the same meaning.

The scenario generation unit 11 can generate a knowledge graph as a scenario. The knowledge graph expresses a connection among various kinds of knowledge in a graph structure. That is, the scenario generated by the scenario generation unit 11 may express a connection among the knowledge. Knowledge may also be expressed as external knowledge. For example, in the case of the people flow simulation, the knowledge may be building information or road information.

The scenario generation unit 11 arranges an agent and an environment as nodes. In other words, the scenario generation unit 11 defines the agent and the environment as nodes. These nodes are referred to as an agent node and an environment node, respectively. As described above, the agent node may be a person, an animal, an automobile, or an autonomous traveling robot. The environment node is an environmental element in the simulation based mainly on geospatial information. That is, the environment node is an environmental element in the simulation in which the agent node is active. Specifically, the environment node is an intersection or a building. That is, the agent node can be regarded as a dynamic element, whereas the environment node can be regarded as a static element.

The scenario generation unit 11 arranges the characteristics of the agent or the environment as nodes. In other words, the scenario generation unit 11 defines the characteristic as a node. This node is referred to as a characteristic node. The characteristics of the agent include a role, an attribute, a decision-making type, a personality, and the like of each agent. That is, the characteristic of the agent is an element that affects the action pattern of each agent in the simulation. In other words, the agents with different characteristics may have different action patterns in the simulation.

Here, a case where the scenario generation unit 11 generates a scenario in a simulation at the time of disaster will be considered as an example. In this case, the role of the agent may be classified according to, for example, the occupation of the agent. That is, the role of the agent is, for example, “resident (ordinary citizen)” or “guide”. Furthermore, the attribute of the agent may be classified according to, for example, the state of the agent, the age of the agent, the traveling speed of the agent, and the wideness of the field of view of the agent. The attribute of the agent is, for example, “elderly person” or “disabled person”. Furthermore, the decision-making type of the agent may be classified according to, for example, the agent's familiarity with the place. The decision-making type of the agent is, for example, “familiar with the place”, “slightly familiar with the place”, or “not familiar with the place”.

The characteristics of the environment include the size, situation, and the like of each environmental element. Similarly to the above, a case where the scenario generation unit 11 generates a scenario in a simulation at the time of disaster will be considered. In this case, the environment node is, for example, an intersection or a building. Furthermore, in this case, the characteristics of the environment may be the size of the intersection and whether passing is possible. In addition, the characteristics of the environment may be the structure type of the building, the number of floors of the building, the capacity of the agent, and the application of the building.

Here, the scenario generation unit 11 may not provide the characteristic node of the environment. That is, the scenario generation unit 11 may define characteristics individually for each environment node.

The scenario generation unit 11 that has arranged the agent node, the environment node, and the characteristic node connects the arranged nodes with an edge. Specifically, the scenario generation unit 11 connects any environment node and another environment node. In addition, the scenario generation unit 11 connects any agent node and another agent node. Furthermore, the scenario generation unit 11 connects any environment node and any agent node. Furthermore, the scenario generation unit 11 connects any agent node or environment node and a characteristic node. The scenario generation unit 11 may or may not be able to connect any characteristic node and another characteristic node.

An edge connecting any environment node and another environment node constructs an environment network in a scenario. For example, in a case where two intersections are defined as environment nodes, the connected edge can be regarded as a road by connecting the intersections. Furthermore, a relationship between agents can be defined by connecting any agent node and another agent node. For example, in a case where two residents are defined as two agent nodes, it is possible to define that the residents are in an acquaintance relationship by connecting the residents. The acquaintance relationship may include, for example, a friendship, a family relationship, and the like. Furthermore, an initial arrangement of agents can be defined by connecting any environment node and any agent node. For example, in a case where an intersection and a resident are defined as an environment node and an agent node, respectively, the initial arrangement of the resident can be determined as the intersection by connecting these nodes.

Then, a characteristic of each agent or environment can be defined by connecting any agent node or environment node and a characteristic node. For example, a case where a resident is defined as an agent node and a plurality of different characteristic nodes are defined as a decision-making type of the agent will be considered. In this case, the decision-making type of the resident can be defined by connecting the agent node and any decision-making type.

Here, the scenario generation unit 11 may connect a node and an edge. For example, an agent node may be connected to an edge connecting an environment node and another environment node. In this case, the edge can be defined as a location of the initial arrangement of the agent node connected to the edge. In this case, a connection point of the agent node at the edge may be defined as a new environment node.

It is assumed that the scenario generation unit 11 connects the nodes according to a predetermined rule. The predetermined rule may be paraphrased as a predetermined prerequisite. The predetermined rule prevents connection between specific nodes. For example, in a case where there is an environment node that is not assumed as an initial arrangement destination of a certain agent node, the predetermined rule includes not arranging the agent node at the environment node. Furthermore, the predetermined rule may include that number of connections between the agent node and the environment node is only one, or may include preventing connection between environment nodes not assumed as environments in the simulation. The predetermined rule may be determined in advance or may be determined by a probability distribution. In a case where the predetermined rule is determined by the probability distribution, the probability distribution may be set such that the connection probability between nodes for preventing connection becomes 0.

In addition, the scenario generation unit 11 may or may not randomly connect nodes for connection between connectable nodes. In other words, the scenario generation unit 11 may randomly determine the connection relationship, or may intentionally determine the connection relationship for the nodes. That is, in a case where there are a plurality of nodes of the same type that can be connected to a certain node, the scenario generation unit 11 may determine the nodes to be connected by a uniform probability distribution or may determine the nodes to be connected by a weighted probability distribution. Here, the type of node may be a classification based on the type of node such as an agent node, an environment node, or a characteristic node, or may be a classification based on the characteristic of the agent node or the environment node.

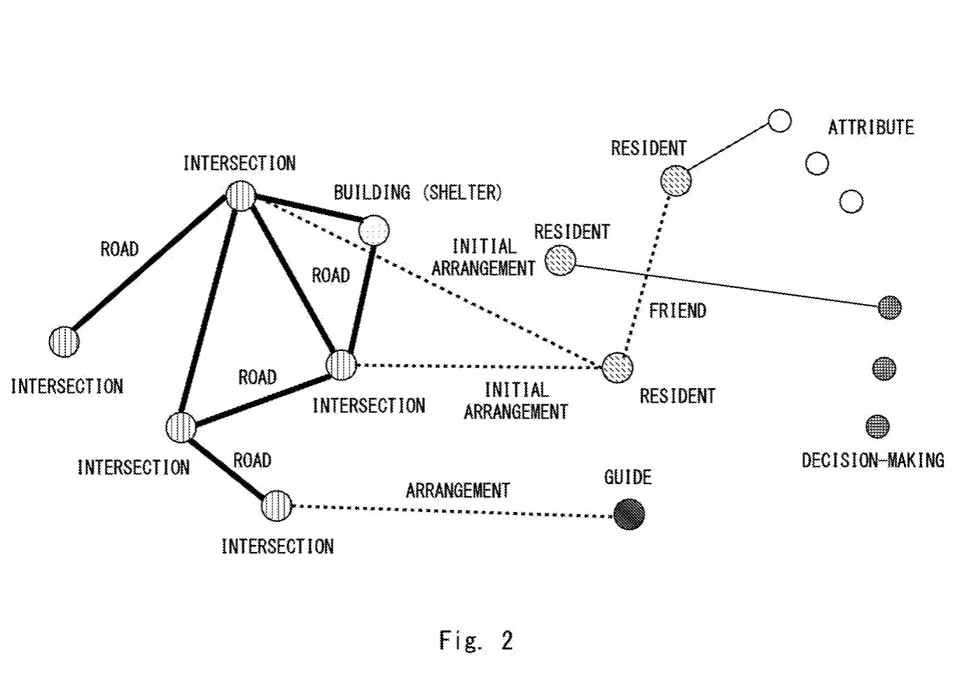

Here, a specific example of the graph structure generated by the scenario generation unit 11 will be described with reference to the drawings. FIG. 2 is an example of a graph structure generated by the scenario generation unit 11. FIG. 2 is a graph structure of a scenario in a people flow simulation at the time of disaster. In FIG. 2, the agent node includes three resident nodes and one guide node. The role of the agent is defined in each agent node. That is, the attribute of the agent is not arranged as a characteristic node on the graph structure of FIG. 2. In addition, the environment node includes five intersection nodes and one building (shelter) node.

In FIG. 2, the characteristic node includes three decision-making nodes and three attribute nodes. The decision-making node represents, for example, agent’s familiarity with the place. Specifically, it is assumed that the three decision-making nodes each represents “familiar with the place and moving to the nearest destination by the shortest route”, “heading to the most famous destination for the time being”, and “not familiar with the place and following the person in front”. Furthermore, the attribute node represents, for example, the state of the agent. Specifically, the three attribute nodes each represents “healthy person”, “elderly person”, and “disabled person”.

The scenario generation unit 11 can define an environment in a scenario by connecting the environment nodes. For example, a road network may be constructed by connecting the intersection node and another intersection node. In addition, a location of a building (shelter) on a road network can be defined by arranging a building (shelter) node.

Furthermore, the scenario generation unit 11 can determine the initial arrangement of the agent by connecting the agent node and the environment node. For example, the resident can be arranged at the intersection by connecting the resident node and the intersection node. Furthermore, the scenario generation unit 11 can define a relationship between agents by connecting the agent nodes. For example, it is possible to define that the residents have a friendship by connecting the two resident nodes. This can be understood as that the residents join and act in the simulation.

Furthermore, the scenario generation unit 11 can define the characteristics of each agent by connecting the agent node and the characteristic node. For example, it is possible to define the resident’s familiarity with the place by connecting the resident node and the decision-making node. In addition, the state of the resident can be defined by connecting the resident node and the attribute node. In FIG. 2, a node indicating the characteristic of the environment is not arranged.

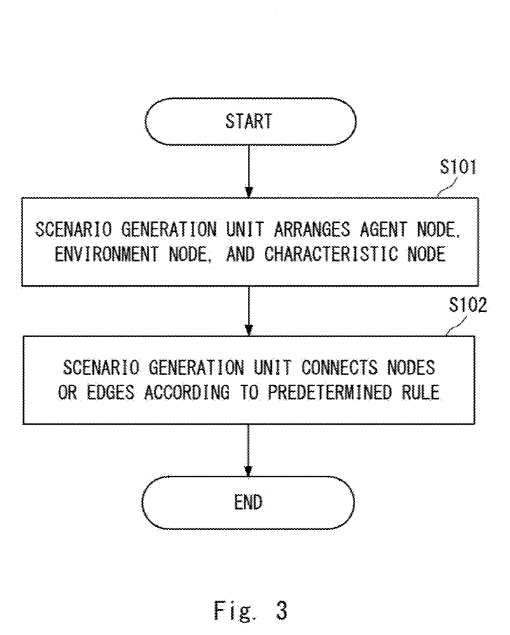

Next, a flow of processing operation by the data processing system 1 will be described. FIG. 3 is a flowchart illustrating an example of a processing operation of the data processing system 1. First, the scenario generation unit 11 arranges an agent node, an environment node, and a characteristic node (S101). Here, the scenario generation unit 11 may arrange any of the agent node, the environment node, and the characteristic node beforehand. In other words, any arrangement order of the nodes by the scenario generation unit 11 may be adopted Next, the scenario generation unit 11 connects nodes or edges according to a predetermined rule (S102). That is, the scenario generation unit 11 connects any agent nodes, environment nodes, or characteristic nodes. Here, the scenario generation unit 11 may connect a node and an edge. Furthermore, the scenario generation unit 11 may perform the connection relationship of any of the agent nodes, the environment nodes, and the characteristic nodes beforehand. In other words, any connecting order of the nodes by the scenario generation unit 11 may be adopted. Through the above steps, the data processing system 1 generates the graph structure as a scenario.

As described above, the data processing system 1 according to the first example embodiment arranges the characteristic of the agent or the environment as a node in the graph structure and connects it with the agent node or the environment node, so that the characteristic of the agent or the environment can be reflected on the scenario. Since the graph structure based on the technology according to C. Chang, et al.,“ LLMScenario: Large Language Model Driven Scenario Generation,” IEEE Transactions on Systems, Man, Cybernetics: Systems, Vol. 54, Issue 11, November 2024, is generated using data that has been utilized as open data, it is possible to reflect a physical situation such as a relationship between a vehicle and a road and a positional relationship between vehicles on the scenario, but it is not possible to directly reflect this on the scenario in consideration of internal parameters such as a personality and a function of an agent. This is because such internal parameters cannot be found from the open data. As a result, in this technology, there is a case where the function possessed by the advanced simulation cannot be fully utilized. This is because it is difficult to model an agent and the like in consideration of the personality and the function from the open data. That is, it is difficult for the technology to directly generate a scenario beyond the information in the open data.

The data processing system 1 according to the first example embodiment can directly reflect the internal parameters such as the role and attribute, and the personality/decision-making of the agent beyond the information in the open data on the scenario. Therefore, the data processing system 1 can generate agents with various behaviors for each scenario, and can execute a more complex simulation. In addition, the data processing system 1 can define the structure of the graph in the scenario and the elements in the graph in accordance with the functions and the calculation processing possessed by the simulation. Therefore, the data processing system 1 can fully utilize the functions possessed by the advanced simulation. As a result, the data processing system 1 can generate a scenario with high comprehensiveness.

The characteristics of the agent that can be reflected on the scenario generated by the data processing system 1 are, for example, a role of the agent, an attribute of the agent, and a decision-making type of the agent. By reflecting these on the scenario as the characteristics of the agent, it is possible to change the action pattern of the agent during simulation for each scenario.

In the technology according to C. Chang, et al.,“ LLMScenario: Large Language Model Driven Scenario Generation,” IEEE Transactions on Systems, Man, Cybernetics: Systems, Vol. 54, Issue 11, November 2024, the feasibility of the generated scenario is evaluated by an evaluation formula. This is to determine whether there is no contradiction in the occurrence procedure and contents of the event in the generated scenario or whether the generated scenario is appropriate as a scenario to be considered. The technology according to C. Chang, et al.,“ LLMScenario: Large Language Model Driven Scenario Generation,” IEEE Transactions on Systems, Man, Cybernetics: Systems, Vol. 54, Issue 11, November 2024, excludes a scenario with low feasibility by evaluating the generated scenario. The calculation by the evaluation formula becomes complicated depending on the scale of the simulation, and in the case of a large-scale simulation, there is a problem that a large calculation cost is generated in the evaluation, such as a necessity to execute the simulation in order to perform the evaluation occurs.

However, in the data processing system 1 according to the first example embodiment, the nodes are connected according to a predetermined rule, and hence the feasibility of the scenario can be ensured by generating the scenario conforming to the rule. In other words, the data processing system 1 can ensure the quality of the generated scenario. That is, the connection between specific nodes can be prevented by the data processing system 1 connecting the nodes according to a predetermined rule. As a result, it is possible to eliminate occurrence of an impossible scenario condition or coexistence in a scenario. As a result, the simulation using the scenario can be appropriately operated. In other words, the data processing system 1 can filter in advance the scenario to be generated by generating the scenario according to the rule. As a result, in the data processing system 1, the calculation cost caused by the technology according to C. Chang, et al.,“ LLMScenario: Large Language Model Driven Scenario Generation,” IEEE Transactions on Systems, Man, Cybernetics: Systems, Vol. 54, Issue 11, November 2024, can be suppressed.

In addition, the data processing system 1 according to the first example embodiment generates a scenario by the graph structure, but in the related art, the scenario can be generated in a tabular format. In the case of a tabular format scenario, a plurality of tabular files usually need to be prepared. This is for organizing the types of data and making the data easy to understand, and for facilitating correction of the data. In a case of preparing tabular format data, a plurality of pieces of external knowledge are required in order to perform control in such a way as not to input an inappropriate value (a value outside the definition etc.) as data. At this time, in a case where the reference destination of the knowledge passes through another knowledge in the scenario, that is, in a case where the reference of the data is a so-called multi-hop, a problem arises in that the processing of the data becomes complicated. On the other hand, in the case of the scenario of the graph structure generated by the data processing system 1, since the scenario can be expressed by a single graph structure, it is not necessary to prepare a plurality of files, and processing of data is easy.

Furthermore, even for the tabular format scenario, geospatial information may be required. The data resource of the geospatial information is often a graph structure such as a road network. Therefore, in a case where the tabular format scenario is generated using the geospatial information, it becomes necessary to perform processing of manually converting the geospatial information of the graph structure into the data structure by a Geographic Information System (GIS) or the like. On the other hand, the scenario can be automatically generated using the geospatial information by using the data processing system 1.

Even in the case where the tabular format scenario is used, a case where the geospatial information of the graph structure is not used can also be considered. In this case, it may not be possible to determine whether all the components of the scenario are included only with the tabular format data. For example, if data regarding a specific road in the road network does not exist in the scenario, a scenario including the road is not generated. On the other hand, it is possible to determine whether all the components of the scenario are included by generating the scenario of the graph structure using the data processing system 1.

In addition, in the related art, there is also a method of generating a scenario in a text (document) format, but the text format needs to be converted into a tabular format or the like in order to be input as the scenario into a simulation. Furthermore, in a case where the scenario in the text format is used in consideration of a case where all the information necessary for executing the simulation is not included in the text, it is necessary to define processing for interpolating the missing portion in advance or to prepare a database. On the other hand, such a problem does not arise by generating the scenario of the graph structure using the data processing system 1.

### Second Example Embodiment

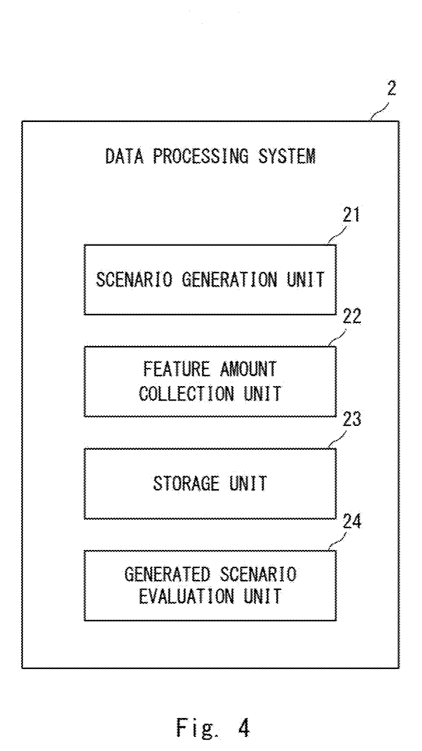

Next, a second example embodiment according to the present disclosure will be described. FIG. 4 is a block diagram illustrating a configuration of a data processing system 2 according to the present disclosure. The data processing system 2 includes a scenario generation unit 21, a feature amount collection unit 22, a storage unit 23, and a generated scenario evaluation unit 24. Similarly to the data processing system 1, the data processing system 2 is a system for generating a scenario for executing a multi-agent simulation. That is, the data processing system 2 is obtained by adding the configurations of the feature amount collection unit 22, the storage unit 23, and the generated scenario evaluation unit 24 to the data processing system 1. Repetitive description between the scenario generation unit 21 in the data processing system 2 and the scenario generation unit 11 in the data processing system 1 will be appropriately omitted.

The scenario generation unit 21 may generate a scenario based on data whose original data structure is a graph structure, or may generate a scenario based on tabular format data. In other words, the scenario generation unit 21 may generate a knowledge graph as a scenario based on the tabular format data. Hereinafter, the tabular format and the graph structure are uniformly treated as scenarios.

The scenario generation unit 21 can generate a scenario based on a feature amount of a scenario previously generated by the scenario generation unit 21. The feature amount represents the feature of the scenario generated by the scenario generation unit 21. In particular, the feature amount is to be the target of comparison in a case of comparing the scenarios generated by the scenario generation unit 21. The feature amount may also be referred to as a feature expression. The feature amount may be one or more for one scenario.

The reason as to why there may be a plurality of feature amounts for one scenario is as follows. That is, one scenario is data including a plurality of parameters (conditions). Therefore, the feature amount may be defined for each of those parameters. Furthermore, the feature amount of the scenario itself may be defined by a combination of a plurality of feature amounts.

The feature amount may be, for example, a connection distribution in a graph structure. The connection distribution is, for example, statistical information of a connection frequency between a node or an edge and another node or edge in the graph structure. In other words, the connection distribution is, for example, statistical information of the connection frequency between the nodes and the edges in the graph structure. The statistical information of the connection frequency may be represented by a histogram or may be represented in a tabular format. The statistical information of the connection frequency is typically a discrete distribution, but may be a continuous distribution. In the following description, the statistical information of the connection frequency is treated as being represented by a discrete distribution.

The statistical information of the connection frequency between the nodes and the edges in the graph structure will be described. The scenario generation unit 21 may connect a node and a node, or may connect a node and an edge. Here, in a case where a node and a node are connected based on a predetermined rule, it is assumed that there are a plurality of nodes connectable to a certain type of node. In this case, the scenario generation unit 21 may determine the node to be connected by a uniform probability distribution, or may determine the node to be connected by a weighted probability distribution. The connection frequency between a node and another node is a degree at which a certain type of node is repeatedly connected to the connectable node.

For example, in the scenario generation in the people flow simulation, a case will be considered in which the scenario generation unit 21 determines the initial arrangement of the resident by connecting the resident serving as the agent node and the intersection serving as the environment node. Here, it is assumed that there are a plurality of residents and there are a plurality of intersections to which each resident can be connected. In this case, the scenario generation unit 21 connects each resident and the intersection according to some kind of probability distribution. In this example, the connection frequency between the node and another node is, for example, the number of times that the resident has connected to each intersection.

Furthermore, a case where the scenario generation unit 21 connects a node and an edge based on a predetermined rule, and there are a plurality of edges connectable to a certain type of node will be considered. In this case, the connection frequency between the node and the edge is a degree at which a certain type of node is repeatedly connected to the connectable edge.

For example, in the scenario generation in the people flow simulation, a case will be considered in which the scenario generation unit 21 arranges residents on a road by connecting a plurality of resident nodes and a road that is an edge connecting a plurality of intersections. In this case, the connection frequency between the node and the edge may be the number of times the resident has connected to each road.

The statistical information of the connection frequency is obtained by aggregating the connection frequencies between a node and another node or the connection frequencies between a node and an edge. The statistical information of the connection frequency may be aggregated only for the connection frequency in one scenario, or may be aggregated together with a scenario previously generated by the scenario generation unit 21.

That is, the scenario generation unit 21 can generate a scenario based on the statistical information of the connection frequency between the nodes and the edges in the graph structure related to the scenario previously generated by the scenario generation unit 21. For example, the scenario generation unit 21 can assume the statistical information as a probability distribution and generate a scenario based on the probability distribution.

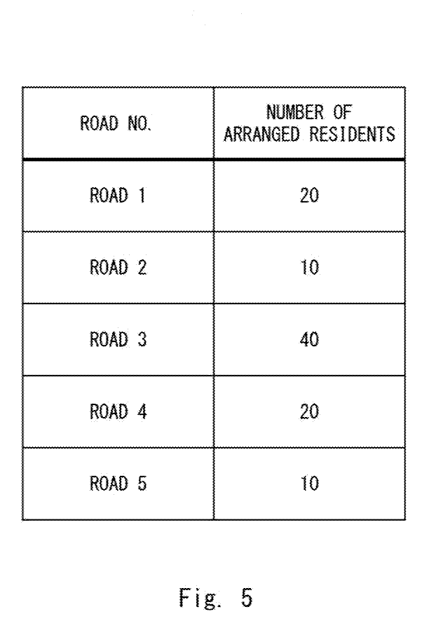

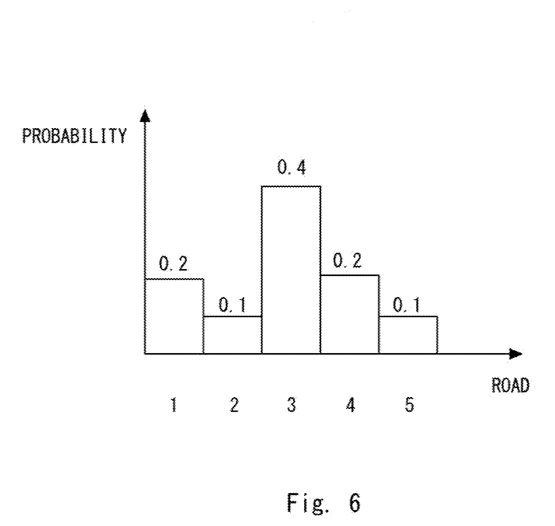

The above will be exemplarily described with reference to the drawings. FIG. 5 is a table illustrating statistical information of the connection frequency between the edge and the node. Furthermore, FIG. 6 is a histogram illustrating statistical information of the connection frequency between the edge and the node For example, a case where the scenario generation unit 21 generates a scenario in the people flow simulation will be considered. It is assumed that, in generating a scenario, the scenario generation unit 21 arranges residents (agent nodes) on roads (edges) connecting the intersections (environment nodes). As a result of the scenario generation unit 21 arranging the residents on the roads, the residents are arranged on the respective roads.

In FIGS. 5 and 6, it is assumed that the number of residents to be arranged by the scenario generation unit 21 is 100, and there are five roads as arrangement destinations. As a result of the scenario generation unit 21 arranging the residents, 20 people are arranged on road 1, 10 people are arranged on road 2, 40 people are arranged on road 3, 20 people are arranged on road 4, and 10 people are arranged on road 5. As illustrated in FIG. 5, the relationship between the roads and the number of arranged residents can be represented in a table.

Here, the scenario generation unit 21 can regard statistical information of the connection frequencies between the roads and the number of arranged residents in FIG. 5 as a probability distribution. That is, the scenario generation unit 21 can assume that the probability of being arranged on road 1 is 0.2, the probability of being arranged on road 2 is 0.1, the probability of being arranged on road 3 is 0.4, the probability of being arranged on road 4 is 0.2, and the probability of being arranged on road 5 is 0.1.

This probability distribution can be expressed by a histogram as illustrated in FIG. 6. In the histogram of FIG. 6, the horizontal axis represents the road, and the vertical axis represents the arrangement probability of the residents. That is, the histogram represents that the arrangement probability of road 1 is 0.2, the arrangement probability of road 2 is 0.1, the arrangement probability of road 3 is 0.4, the arrangement probability of road 4 is 0.2, and the arrangement probability of road 5 is 0.1. As described above, the scenario generation unit 21 can regard the statistical information of the connection frequency between the nodes and the edges for the graph structure related to the scenario previously generated by the scenario generation unit 21 as the probability distribution, and generate a scenario based on the probability distribution.

In a case where the scenario generation unit 21 generates a scenario based on the probability distribution, the scenario generation unit 21 can generate a scenario including a probability distribution in which the similarity is greater than a predetermined value. In other words, the scenario generation unit 21 can generate a scenario whose probability distribution is similar to a certain scenario. The similarity may be calculated as a distance based on the optimal transport theory, or may be calculated as a Kullback-Leibler (KL) information amount (divergence). That is, the scenario generation unit 21 can generate a scenario with a small distance based on the optimal transport theory with respect to a certain scenario.

Furthermore, the scenario generation unit 21 can generate a scenario including a probability distribution in which the similarity is smaller than a predetermined value. In other words, the scenario generation unit 21 can generate a scenario whose probability distribution is not similar to a certain scenario. In a case where the similarity is calculated as the distance based on the optimal transport theory, the scenario generation unit 21 can generate a scenario in which the distance based on the optimal transport theory is large with respect to a certain scenario.

Returning to FIG. 4, the description of the configuration of the data processing system 2 will be continued. The feature amount collection unit 22 collects the feature amounts of the scenario generated by the scenario generation unit 21. The feature amount collection unit 22 may collect the statistical information of the connection frequency between a node or an edge and another node or edge in the graph structure as the feature amount of the scenario. In other words, the feature amount collection unit 22 may collect the statistical information of the connection frequency between the nodes and the edges as the feature amount of the scenario. Here, the connection frequency between the nodes and the edges may be referred to as co-occurrence between nodes.

The feature amount collection unit 22 may directly extract the feature amount of the scenario generated by the scenario generation unit 21 from the graph structure itself. For example, the feature amount collection unit 22 may extract a feature amount using a graph neural network. In this case, the graph neural network uses, for example, a graph structure and a predetermined feature amount as teacher data. Then, the feature amount collection unit 22 may collect the feature amount by inputting the graph structure and extracting the feature amount in the graph neural network.

The storage unit 23 is an example of a nonvolatile storage device such as a hard disk or a flash memory. The storage unit 23 stores the feature amounts of the scenario collected by the feature amount collection unit 22 for the scenario generated by the scenario generation unit 21. That is, in a case where the feature amount is the statistical information of the connection frequency between the nodes and the edges, the storage unit 23 stores the statistical information. Furthermore, the storage unit 23 may store a scenario. At that time, the storage unit 23 may store the scenario and the feature amount in association with each other. In a case where a plurality of feature amounts is included in one scenario, the storage unit 23 may organize and store the plurality of feature amounts together.

Furthermore, the storage unit 23 may store information necessary for the scenario generation unit 21 to generate the scenario. For example, the storage unit 23 may store information related to a node, or may store a predetermined rule for connecting the nodes. Specifically, the storage unit 23 may store information related to the environment node, information related to the agent node, and information related to the characteristic node.

The generated scenario evaluation unit 24 calculates similarity between the feature amount of the scenario generated by the scenario generation unit 21 and the feature amount of the scenario stored in the storage unit 23. Here, the generated scenario evaluation unit 24 may target one feature amount in the scenario generated by the scenario generation unit 21, or may target a plurality of feature amounts. In a case where the feature amount of the scenario is the statistical information of the connection frequency between the nodes and the edges, the generated scenario evaluation unit 24 may calculate the similarity by regarding the statistical information as a probability distribution. For example, the generated scenario evaluation unit 24 may calculate the similarity as a distance based on the optimal transport theory or as a KL information amount (divergence). Furthermore, the generated scenario evaluation unit 24 compares the calculated similarity, and determines whether the similarity is larger or smaller than a predetermined value. Such a function by the generated scenario evaluation unit 24 is referred to as similarity evaluation.

The generated scenario evaluation unit 24 can perform correction processing for the scenario generated by the scenario generation unit 21. For example, in the scenario generation by the scenario generation unit 21, if there are a plurality of nodes of the same type that can be connected to a certain node, the generated scenario evaluation unit 24 may perform processing of correcting the probability distribution for determining the connecting node.

In addition, the generated scenario evaluation unit 24 can perform a search processing of a scenario stored in the storage unit 23 in the similarity evaluation. For example, the generated scenario evaluation unit 24 can present the scenario stored in the storage unit 23 to the user. Specifically, the generated scenario evaluation unit 24 may present, to the user, some or all of the scenarios with a similarity equal to or greater than a certain value with the generated scenario. In addition, the generated scenario evaluation unit 24 can sort the scenarios to be compared, that is, the scenarios stored in the storage unit 23, according to the similarity with the generated scenario.

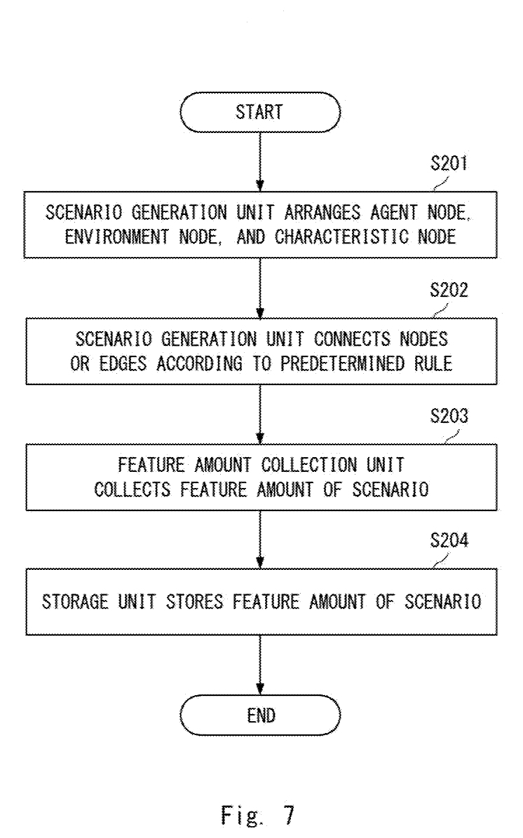

Next, a flow of processing operation by the data processing system 2 will be described. FIG. 7 is a flowchart illustrating an example of a processing operation of the data processing system 2. First, the scenario generation unit 21 arranges an agent node, an environment node, and a characteristic node (S201). Here, the scenario generation unit 21 may arrange any of the agent node, the environment node, and the characteristic node beforehand. In other words, any arrangement order of the nodes by the scenario generation unit 21 may be adopted. Next, the scenario generation unit 21 connects nodes or edges according to a predetermined rule (S202). That is, the scenario generation unit 21 connects any agent nodes, environment nodes, and characteristic nodes. Here, the scenario generation unit 21 may connect a node and an edge. Furthermore, the scenario generation unit 21 may perform the connection relationship of any of the agent nodes, the environment nodes, and the characteristic nodes beforehand. In other words, any connecting order of the nodes by the scenario generation unit 21 may be adopted. Thereafter, the feature amount collection unit 22 collects the feature amount of the scenario (S203). The storage unit 23 then stores the feature amount of the scenario (S204).

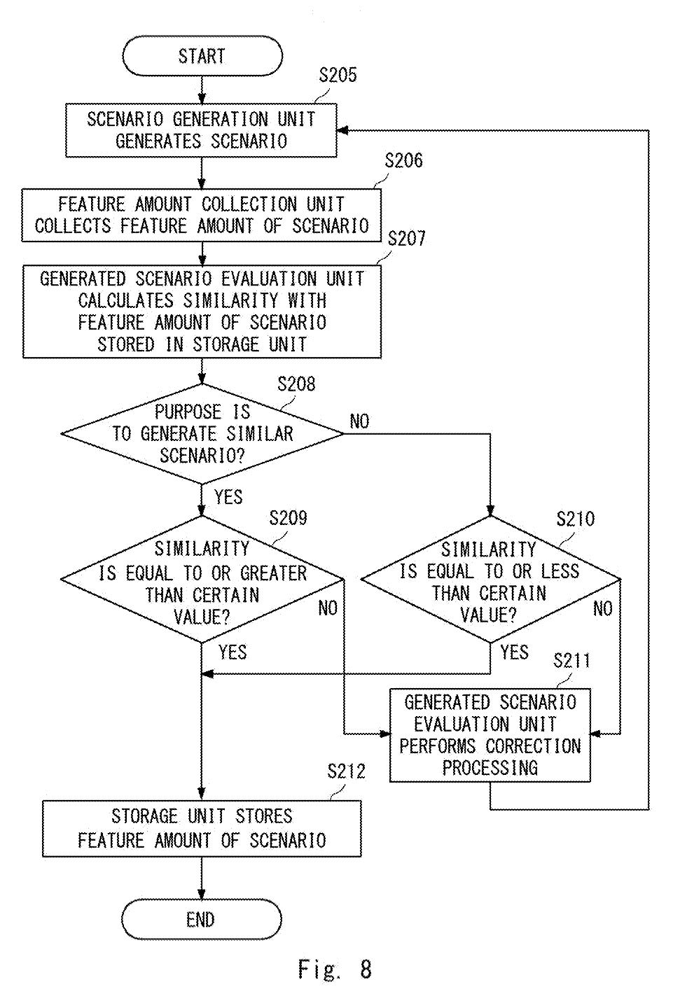

Next, a flow in a case where the scenario generation unit 21 generates a scenario based on the similarity will be described. FIG. 8 is a flowchart illustrating an example of a flow in a case where the scenario generation unit 21 generates a scenario based on the similarity. First, the scenario generation unit 21 generates a scenario based on a predetermined rule and a predetermined probability distribution (S205). Next, the feature amount collection unit 22 collects the feature amount of the generated scenario (S206). Thereafter, the generated scenario evaluation unit 24 refers to the storage unit 23 and calculates the similarity between the feature amount of the scenario stored in the storage unit 23 and the feature amount of the scenario generated by the scenario generation unit 21 (S207). Here, the generated scenario evaluation unit 24 may target all scenarios stored in the storage unit 23, or may target some scenarios. In addition, the generated scenario evaluation unit 24 may calculate the similarity with all the feature amounts in the scenario stored in the storage unit 23, or may calculate the similarity with some feature amounts.

Next, the generated scenario evaluation unit 24 determines whether the purpose is to generate a similar scenario (S208). That is, the generated scenario evaluation unit 24 determines whether the purpose of the scenario generation unit 21 is to generate a scenario similar to the scenario stored in the storage unit 23. Here, a purpose of generating a similar scenario means a purpose of generating a scenario of a feature amount similar to the feature amount stored in the storage unit 23. On the other hand, a purpose of not generating a similar scenario means a purpose of generating a scenario of a feature amount that is not similar to the feature amount stored in the storage unit 23.

In a case where the purpose of generating a scenario this time is to generate a similar scenario, the generated scenario evaluation unit 24 determines whether the similarity between the scenarios is equal to or greater than a certain value (S209). Here, if the similarity is regarded as a distance according to the optimal transport theory, the generated scenario evaluation unit 24 determines whether the distance between the scenarios is equal to or less than a certain value. If the similarity is equal to or greater than the certain value, the storage unit 23 stores the feature amount of the scenario (S212). If the similarity is not equal to or greater than the certain value, the generated scenario evaluation unit 24 performs correction processing (S211). The correction processing by the generated scenario evaluation unit 24 is, for example, processing of correcting a probability distribution for determining a connecting node. After the correction processing, the scenario generation unit 21 generates the scenario again (S205). The flow is repeated until the similarity of the scenarios becomes equal to or greater than a certain value. In a case where the scenario that satisfies the requirement of similarity can be generated, the storage unit 23 stores the feature amount of the scenario (S212). Here, the generated scenario evaluation unit 24 may present the scenarios stored in the storage unit 23 to the user, or may sort the scenarios stored in the storage unit 23.

In a case where the purpose of generating a scenario this time is not to generate a similar scenario, the generated scenario evaluation unit 24 determines whether the similarity between the scenarios is equal to or less than a certain value (S210). Here, if the similarity is regarded as a distance according to the optimal transport theory, the generated scenario evaluation unit 24 determines whether the distance between the scenarios is equal to or greater than a certain value. If the similarity is equal to or less than the certain value, the storage unit 23 stores the feature amount of the scenario (S212). If the similarity is equal to or greater than the certain value, the generated scenario evaluation unit 24 performs the correction processing (S211). After the correction processing, the scenario generation unit 21 generates the scenario again (S205). The flow is repeated until the similarity of the scenarios becomes equal to or less than a certain value. In a case where the scenario that satisfies the requirement of similarity can be generated, the storage unit 23 stores the feature amount of the scenario (S212). Here, the generated scenario evaluation unit 24 may present the scenarios stored in the storage unit 23 to the user, or may sort the scenarios stored in the storage unit 23.

As described above, the data processing system 2 according to the second example embodiment can compare scenarios by the feature amount by collecting the feature amount from the scenario generated by the scenario generation unit 21 and storing the feature amount. The scenario based on the feature amount of the scenario previously generated by the scenario generation unit 21 can be generated by comparing the feature amount of the scenario generated by the scenario generation unit 21 with the feature amount of the scenario stored in the storage unit 23.

The scenario whose feature amount is similar means that the content and the structure of the scenarios are similar to each other. On the contrary, the scenario whose feature amount is not similar means that the content and the structure of the scenarios are not similar to each other. That is, by generating the scenario based on the feature amount, the scenario can be generated based on comparison with the scenario generated so far.

In the related art, since the variables and parameters of the scenario are manually set, there was a problem that the work cost is large in a case of generating the scenario. This is because the work of generating the scenario is carefully performed based on knowledge of experts. In addition, due to the advancement of the functions of the simulation, the number of various parameters included in the scenario becomes enormous, and it is difficult to generate an appropriate scenario.

According to the data processing system 2 of the second example embodiment, since the scenario generation work can be automated, the cost of the simulation operation can be reduced, and the scenario that cannot be searched manually can be generated by enabling the scenario generation based on the feature amount and a scenario with higher comprehensiveness can be generated.

The generated scenario evaluation unit 24 according to the data processing system 2 can calculate the similarity between the feature amount of the scenario generated by the scenario generation unit 21 and the feature amount of the scenario stored in the storage unit 23, and evaluate the similarity between the scenarios. As a result, the scenario generation unit 21 can generate a scenario corresponding to the target similarity. That is, the scenario generation unit 21 can generate a scenario with high similarity or a scenario with low similarity.

One of the purposes for the generated scenario evaluation unit 24 to evaluate a scenario with high similarity is to search for the existing scenario stored in the storage unit 23. For example, in a case where the scenario generation unit 21 generates a scenario defining a real-time real situation, the generated scenario evaluation unit 24 can extract a scenario close to the current situation from the storage unit 23 by searching for a scenario with high similarity from the storage unit 23.

On the other hand, one of the purposes of the generated scenario evaluation unit 24 to evaluate a scenario with low similarity is to search for a scenario stored in the storage unit 23 and generate a scenario whose conditions and contents are different from that scenario. That is, the generated scenario evaluation unit 24 can search for and generate an unknown scenario by evaluating a scenario with low similarity.

In a case where the feature amount related to the data processing system 2 is the statistical information of the connection frequency between the nodes and the edges, the data processing system 2 can compare the scenarios with the statistical information. In particular, by regarding the statistical information as a probability distribution, a similar scenario can be generated using the probability distribution. For example, in a case where it is desired to generate a scenario similar to the scenario stored in the storage unit 23, the scenario generation unit 21 can generate a similar scenario by determining a connection relationship between nodes or edges using a probability distribution similar to the probability distribution related to the scenario. Conversely, in a case where it is desired to generate a scenario that is significantly different from and is not similar to the scenario stored in the storage unit 23, the scenario generation unit 21 can generate a scenario that is not similar by determining the connection relationship using a probability distribution that is not similar to the probability distribution related to the scenario.

In a case where the feature amount is regarded as the statistical information of the connection frequency between the nodes and the edges, the statistical information is regarded as a probability distribution, and the generated scenario evaluation unit 24 calculates the similarity of the feature amounts as the distance based on the optimal transport theory, the data processing system 2 can quantitatively calculate the similarity of the scenario. As a result, the data processing system 2 can intentionally generate a similar scenario and an unverified scenario.

In addition, the data processing system 2 can compare scenarios in multiple ways by directly extracting feature amounts from the graph structure itself. The data processing system 2 can, for example, extract the feature amount using the graph neural network. For example, in a case where scenarios are compared from one perspective, comparison can be performed by using a histogram. However, in a case where scenarios are compared from a plurality of perspectives, comparison from a macro viewpoint may be more suitable for analysis than comparison of individual histograms. In such a case, the graph neural network can extract the feature amount of the scenario from the graph structure itself. Therefore, by using the graph neural network, even a more latent element that does not appear in the histogram may be extracted as the feature amount.

### Third Example Embodiment

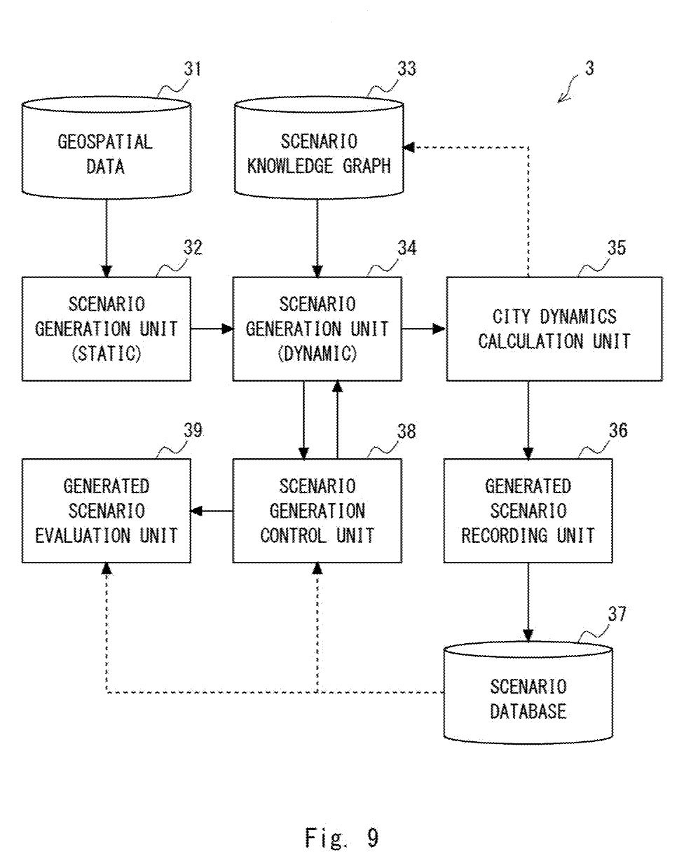

Next, a third example embodiment according to the present disclosure will be described. FIG. 9 is a block diagram illustrating a configuration of a data processing system 3 according to the present disclosure. The data processing system 3 includes geospatial data 31, a scenario generation unit (static) 32, a scenario knowledge graph 33, a scenario generation unit (dynamic) 34, a city dynamics calculation unit 35, a generated scenario recording unit 36, a scenario database 37, a scenario generation control unit 38, and a generated scenario evaluation unit 39. The data processing system 3 is a system for executing a multi-agent simulation, in particular a people flow simulation. That is, the data processing system 3 is a specific configuration for achieving the data processing system 2. Hereinafter, description of each configuration in the data processing system 3 will be appropriately omitted for repetitive portions with the data processing system 1 and the data processing system 2.

The geospatial data 31 stores information related to the environment nodes, i.e., static elements, and a predetermined rule for connecting the environment nodes. Specifically, the geospatial data 31 stores geospatial information-based data, such as road networks and building positions. The geospatial data 31 may store information related to characteristic nodes of the environment. In addition, the geospatial data 31 may store open data or may store undisclosed data. Specifically, the geospatial data 31 may store base map information. The geospatial data 31 may have some of the functions of the storage unit 23 according to the second example embodiment.

The scenario generation unit (static) 32 refers to the information related to the environment nodes stored in geospatial data 31, and connects the environment nodes based on a predetermined rule. The scenario generation unit (static) 32 may refer to the information related to the characteristic node of the environment stored in the geospatial data 31, and connect the environment node and the characteristic node based on a predetermined rule and a predetermined probability distribution. That is, the scenario generation unit (static) 32 generates a scenario of a static element portion with respect to the scenario generation unit 11 according to the first example embodiment and the scenario generation unit 21 according to the second example embodiment. The scenario generation unit (static) 32 may transmit the generated scenario to the scenario generation unit (dynamic) 34.

The scenario knowledge graph 33 stores information related to an agent node, that is, a dynamic element, a characteristic node of the agent, and a predetermined rule for connecting these nodes. Specifically, the scenario knowledge graph 33 stores a role, an attribute, a decision-making type, a personality, and the like of an agent as a characteristic node. The information stored in the scenario knowledge graph 33 may be different depending on the simulation software. That is, the scenario knowledge graph 33 may determine information to be stored according to the function of the simulation software. The scenario knowledge graph 33 may have some functions of the storage unit 23 according to the second example embodiment.

In addition, the scenario knowledge graph 33 may store information related to environment nodes and a predetermined rule for connecting the environment nodes. For example, in a case where the connection state of the environment nodes differs depending on the scenario, the scenario knowledge graph 33 may store information related to a rule corresponding to such a state. For example, in a case where the blocked state of the road differs depending on the scenario, the scenario knowledge graph 33 stores information related to a rule corresponding to such a state. That is, the environment node can also be treated as a dynamic element.

The scenario generation unit (dynamic) 34 refers to information regarding the agent node and the characteristic node of the agent stored in the scenario knowledge graph 33, and connects the agent node and the characteristic node based on a predetermined rule and a predetermined probability distribution. The scenario generation unit (dynamic) 34 may receive a scenario of a static element portion from the scenario generation unit (static) 32. That is, the scenario generation unit (dynamic) 34 may arrange the agent node and the characteristic node in the scenario of the static element portion and connect these nodes after the scenario generation unit (static) 32 generates the scenario of the static element portion. The scenario generation unit (dynamic) 34 generates a scenario of a dynamic element portion for the scenario generation unit 11 according to the first example embodiment and the scenario generation unit 21 according to the second example embodiment.

In a case where the scenario knowledge graph 33 stores information regarding the environment nodes and a predetermined rule for connecting the environment nodes, the scenario generation unit (dynamic) 34 may connect the environment nodes.

The city dynamics calculation unit 35 is a software program that executes simulation using graph structures that are scenarios generated by the scenario generation unit (static) 32 and the scenario generation unit (dynamic) 34 as input data.

The generated scenario recording unit 36 receives the scenarios generated by the scenario generation unit (static) 32 and the scenario generation unit (dynamic) 34 from the city dynamics calculation unit 35, and collects feature amounts thereof. That is, the generated scenario recording unit 36 has a function similar to that of the feature amount collection unit 22 according to the second example embodiment. Specifically, the generated scenario recording unit 36 collects the statistical information of the connection frequency between a node or an edge and another node or edge in the graph structure as the feature amount of the scenario. In addition, the generated scenario recording unit 36 expresses the statistical information as a probability distribution. The generated scenario recording unit 36 may express the probability distribution by a histogram. The probability distribution is typically a discrete distribution, but may be a continuous distribution. The generated scenario recording unit 36 stores the scenario, the feature amount, and the histogram in the scenario database 37.

The scenario database 37 stores the scenarios generated by the scenario generation unit (static) 32 and the scenario generation unit (dynamic) 34 and the probability distribution collected by the generated scenario recording unit 36. The scenario database 37 stores the scenarios and the probability distribution in association with each other. The scenario database 37 has some of the functions of the storage unit 23 according to the second example embodiment.

The scenario generation control unit 38 controls scenario generation by the scenario generation unit (dynamic) 34 based on the probability distribution regarding a connection frequency between predetermined nodes. Specifically, in a case where there are a plurality of nodes of the same type that can be connected to a certain node, the scenario generation control unit 38 determines nodes to be connected by a predetermined probability distribution. The scenario generation control unit 38 may control scenario generation by the scenario generation unit (static) 32 based on the probability distribution. Furthermore, the scenario generation control unit 38 may set the probability distribution as a uniform probability distribution or a weighted probability distribution. The scenario generation control unit 38 may refer to the probability distribution stored in the scenario database 37. The scenario generation control unit 38 has some of the functions of the scenario generation unit 11 according to the first example embodiment and the scenario generation unit 21 according to the second example embodiment.

In addition, the scenario generation control unit 38 determines whether to adopt the generated scenario. That is, the scenario generation control unit 38 determines whether to cause the city dynamics calculation unit 35 to execute simulation using the scenarios generated by the scenario generation unit (static) 32 and the scenario generation unit (dynamic) 34, or to cause the scenario database 37 to store the scenario.

The generated scenario evaluation unit 39 calculates the similarity between the scenarios generated by the scenario generation unit (static) 32 and the scenario generation unit (dynamic) 34 and the scenario stored in the scenario database 37. The generated scenario evaluation unit 39 regards the statistical information of the connection frequency between the nodes and the edges in these scenarios as a probability distribution, and calculates the similarity as a distance based on the optimal transport theory. That is, the generated scenario evaluation unit 39 has a configuration similar to that of the generated scenario evaluation unit 24 according to the second example embodiment.

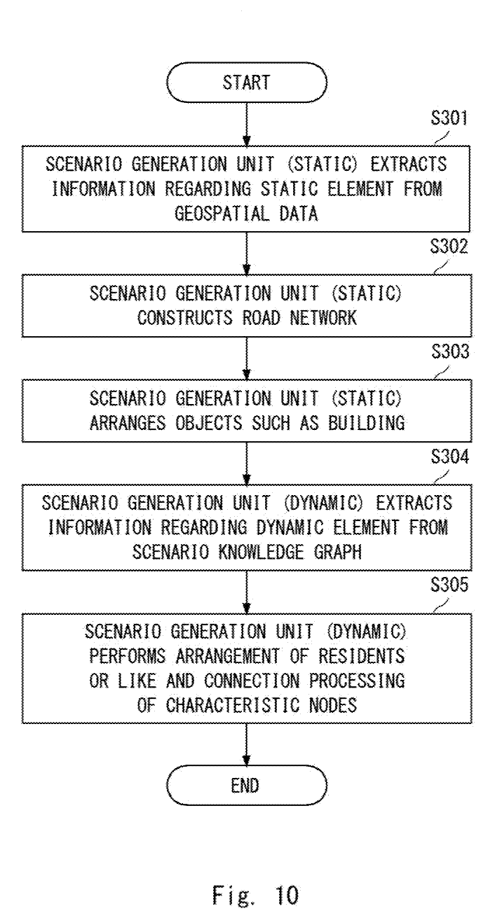

Next, a flow of processing operation by the data processing system 3 will be described. FIG. 10 is a flowchart illustrating an example of scenario generation processing in the data processing system 3. First, the scenario generation unit (static) 32 extracts information regarding the static element from the geospatial data 31 (S301). Next, the scenario generation unit (static) 32 constructs a road network based on a predetermined rule (S302). That is, the scenario generation unit (static) 32 constructs a road network by arranging intersections and connecting predetermined intersections based on the information extracted from the geospatial data 31. Thereafter, the scenario generation unit (static) 32 arranges an object such as a building (S303). Here, the scenario generation unit (static) 32 may simultaneously execute construction of a road network and arrangement of objects such as buildings.

Thereafter, the scenario generation unit (dynamic) 34 extracts information regarding the dynamic element from the scenario knowledge graph 33 (S304). Thereafter, the scenario generation unit (dynamic) 34 performs arrangement of residents and the like and connection processing of characteristic nodes based on a predetermined rule and probability distribution (S305). Here, the connection relationship between the nodes may be determined by the scenario generation control unit 38.

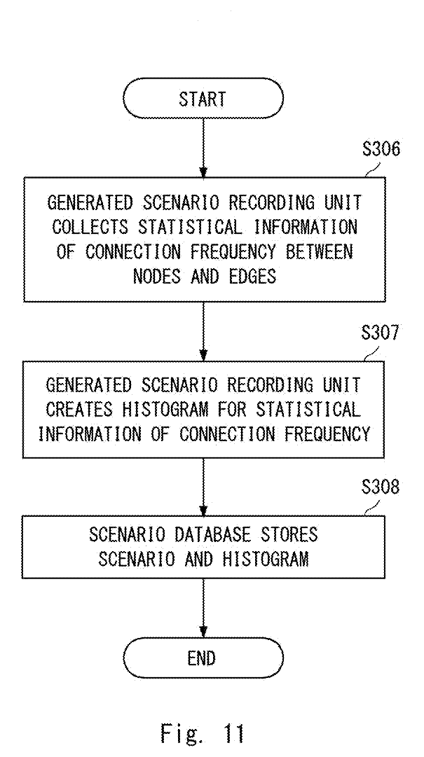

Next, processing for the generated scenario will be described. FIG. 11 is a flowchart illustrating an example of scenario recording processing in the data processing system 3. First, the generated scenario recording unit 36 collects statistical information of the connection frequency between the nodes and the edges in the scenarios generated by the scenario generation unit (static) 32 and the scenario generation unit (dynamic) 34 (S306). Next, the generated scenario recording unit 36 creates a histogram for the statistical information of the connection frequency between the nodes and the edges (S307). Thereafter, the scenario database 37 stores the generated scenario and the histogram (S308).

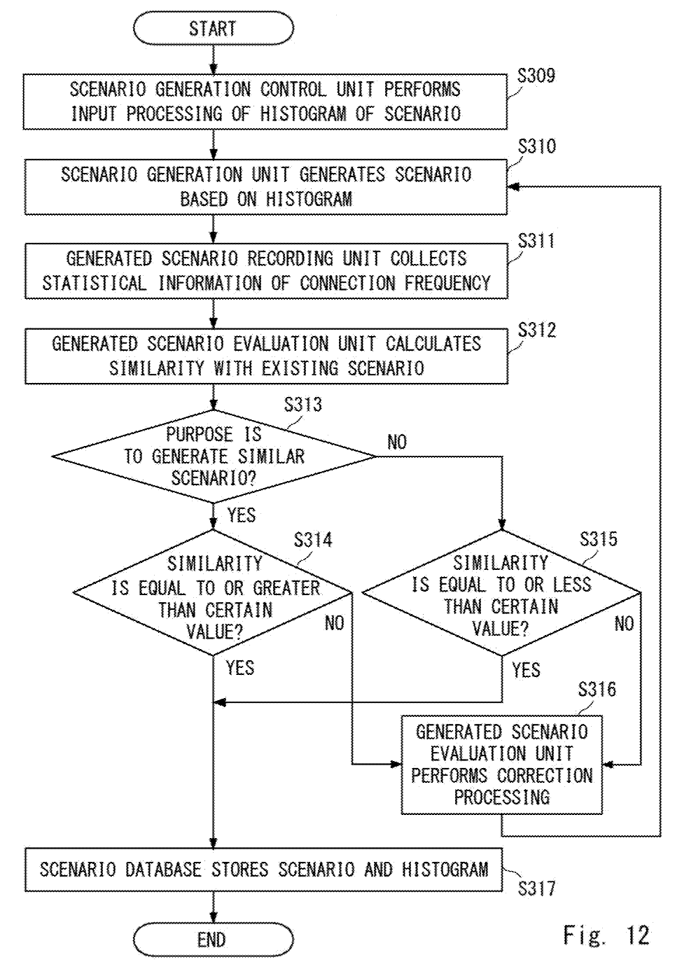

Next, scenario generation based on similarity of the feature amounts of the scenarios will be described. FIG. 12 is a flowchart illustrating an example of scenario generation processing in the data processing system 3. First, the scenario generation control unit 38 performs input processing of a histogram of a scenario (S309). Next, the scenario generation unit (static) 32 and the scenario generation unit (dynamic) 34 generate a scenario based on the input histogram (S310). Here, the scenario generation unit (static) 32 may not generate a scenario of a static element portion. That is, the scenario generation unit (dynamic) 34 may generate a scenario of a dynamic element portion with reference to the static element portion of the scenario stored in the scenario database 37. Next, the generated scenario recording unit 36 collects statistical information of the connection frequency between the nodes and the edges (S311). Thereafter, the generated scenario evaluation unit 39 calculates the similarity with the existing scenario (S312). That is, the generated scenario evaluation unit 39 refers to the feature amount of the scenario stored in the scenario database 37, and calculates the similarity with the scenario generated this time. Here, the generated scenario evaluation unit 39 may calculate the similarity to all the existing scenarios, or may calculate the similarity to only some of the existing scenarios.

Thereafter, the generated scenario evaluation unit 39 determines whether the purpose is to generate a similar scenario (S313). In a case where the purpose of this time is to generate a similar scenario, the generated scenario evaluation unit 39 determines whether the similarity between the scenarios is equal to or greater than a certain value (S314). Specifically, the generated scenario evaluation unit 39 determines whether the distance between the scenarios based on the optimal transport theory is equal to or less than a certain value. If the similarity is equal to or greater than the certain value, the scenario database 37 stores the scenario and the histogram in association with each other (S317). If the similarity is not equal to or greater than the certain value, the generated scenario evaluation unit 39 performs correction processing (S316). The correction processing by the generated scenario evaluation unit 39 is processing of correcting the histogram. After the correction processing, the scenario generation unit (static) 32 or the scenario generation unit (dynamic) 34 generates the scenario again (S310). The flow is repeated until the similarity of the scenarios becomes equal to or greater than a certain value. In a case where the scenario that satisfies the requirement of similarity can be generated, the scenario database 37 stores the scenario and the histogram in association with each other (S317).

In a case where the purpose of generating a scenario this time is not to generate a similar scenario, the generated scenario evaluation unit 39 determines whether the similarity between the scenarios is equal to or less than a certain value (S315). Specifically, the generated scenario evaluation unit 39 determines whether the distance between the scenarios based on the optimal transport theory is equal to or greater than a certain value. If the similarity is equal to or less than the certain value, the scenario database 37 stores the scenario and the histogram in association with each other (S317). If the similarity is equal to or greater than the certain value, the generated scenario evaluation unit 39 performs the correction processing (S316). After the correction processing, the scenario generation unit (static) 32 or the scenario generation unit (dynamic) 34 generates the scenario again (S310). The flow is repeated until the similarity of the scenarios becomes equal to or less than a certain value. In a case where the scenario that satisfies the requirement of similarity can be generated, the scenario database 37 stores the scenario and the histogram in association with each other (S317).

In the flow in FIG. 12, in a case where a scenario that satisfies the requirement of similarity can be generated, the scenario generation control unit 38 may determine whether to adopt the generated scenario. As a result of the scenario generation control unit 38 determining to adopt the generated scenario, the city dynamics calculation unit 35 may execute simulation separately using the scenario. In addition, the generated scenario evaluation unit 39 may present the scenario stored in the scenario database 37 to the user, or may sort the scenarios stored in the scenario database 37.

As described above, the data processing system 3 according to the third example embodiment can generate a scenario with high comprehensiveness and execute a people flow simulation. Specifically, the scenario generation control unit 38 controls scenario generation by the scenario generation unit (static) 32 or the scenario generation unit (dynamic) 34 based on the probability distribution regarding the connection frequency between the nodes. As a result, the data processing system 3 can intentionally generate a scenario with high similarity or scenario with low similarity to the existing scenario stored in the scenario database 37.

In addition, the data processing system 3 calculates the similarity between the scenarios as a distance based on the optimal transport theory. As a result, the data processing system 3 can quantitatively indicate and compare the similarity between the scenarios with the graph structure.

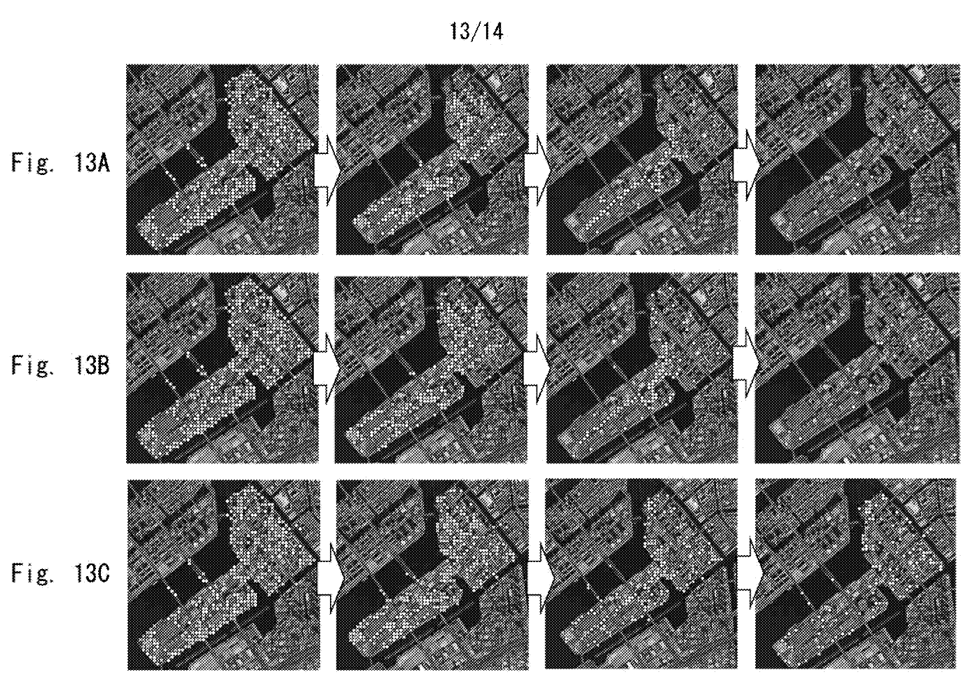

A specific example of a simulation result based on a scenario generated by the data processing system 3 will be described with reference to the drawings. FIG. 13A to FIG. 13C are schematic diagrams illustrating examples of simulation results based on scenarios by the data processing system 3. FIG. 13A to FIG. 13C illustrate images of an island to which a plurality of bridges are connected and its periphery taken from above. An arrow in the image indicates an elapse of time, and a point cloud in the image indicates a person who is an agent. The people flow simulations in FIG. 13A to FIG. 13C are, for example, simulations in a case where it is necessary to move to a destination outside the island by crossing a bridge at the time of disaster. FIG. 13A to FIG. 13C illustrate simulation results of three patterns.

In the scenario generation in FIG. 13A to FIG. 13C, three patterns of decision-making types are prepared as characteristics of a person. That is, at the time of scenario generation in FIG. 13A to FIG. 13C, three decision-making nodes are defined as the characteristic nodes of the agent. Specifically, the decision-making type of the person is allocated to any of a “familiar with the place and moving to the nearest destination by the shortest route” type, a “heading to the most famous destination for the time being” type, or a “not familiar with the place and following the person in front” type. This allocation is performed based on the histogram by the scenario generation control unit 38. The above decision-making types are each referred to as a “familiar with the place” type, a “slightly familiar with the place” type, and a “not familiar with the place” type. It is assumed that the initial arrangement of the person does not change between scenarios.

In the scenario of FIG. 13A, the “familiar with the place” type is 60%, the “slightly familiar with the place” type is 30%, and the “not familiar with the place” type is 10%. In the scenario of FIG. 13B, the “familiar with the place” type is 40%, the “slightly familiar with the place” type is 30%, and the “not familiar with the place” type is 30%. In the scenario of FIG. 13C, the “familiar with the place” type is 20%, the “slightly familiar with the place” type is 10%, and the “not familiar with the place” type is 70%. That is, it can be said that FIG. 13A is a scenario in which there are many people familiar with the place, FIG. 13B is a scenario in which there are various types of people, and FIG. 13C is a scenario in which there are many people not familiar with the place.

As illustrated in FIG. 13A to FIG. 13C, it can be seen that many people can move to the destination outside the island in the case of the scenario in FIG. 13A. In the case of the scenario in FIG. 13B, although it takes more time than FIG. 13A, it can be seen that many people can move to the destination. In the case of the scenario in FIG. 13C, it can be seen that many people cannot move to the destination outside the island and remain on the island.

The data processing system 3 can quantitatively perform the comparison between the scenarios by calculating the similarity between the scenarios in FIG. 13A to FIG. 13C as the distance based on the optimal transport theory. For example, it is assumed that, as a result of the data processing system 3 calculating the distance between the scenarios in FIG. 13A to FIG. 13C, the distance between the scenario in FIG. 13A and the scenario in FIG. 13B is 40.0, the distance between the scenario in FIG. 13B and the scenario in FIG. 13C is 70.0, and the distance between the scenario in FIG. 13A and the scenario in FIG. 13C is 100.0. As the similarity between the scenarios can be quantitatively indicated, the data processing system 3 can determine that, for example, the scenario in FIG. 13A and the scenario in FIG. 13B are relatively similar scenarios, but the scenario in FIG. 13A and the scenario in FIG. 13C are not similar scenarios. As described above, according to the data processing system 3, a scenario with high comprehensiveness can be generated and the comparison between the scenarios can be quantitatively performed.

### Hardware Configuration Example

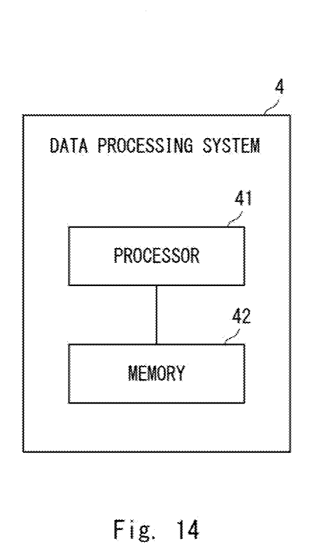

FIG. 14 is a diagram illustrating a hardware configuration example of a data processing system 4 according to the present disclosure. In FIG. 14, the data processing system 4 includes a processor 41 and a memory 42. The processor 41 may be, for example a microprocessor, a Micro Processing Unit (MPU), or a Central Processing Unit (CPU). The processor 41 may include a plurality of processors. The memory 42 includes a combination of a volatile memory and a nonvolatile memory. The memory 42 may include a storage arranged away from the processor 41. In this case, the processor 41 may access the memory 42 through an Input/Output (I/O) interface (not illustrated).

In the above-described example, the program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line. The computer includes various information processing devices such as a PC (personal computer), a server, a CPU, an MPU, a Field Programmable Gate Array (FPGA), and an Application Specific Integrated Circuit (ASIC).

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above example embodiments may also be described as the following supplementary notes, but are not limited to the following.

### Supplementary Note 1

A data processing system including,

a scenario generation unit for arranging an agent in a multi-agent simulation, an environment of the simulation in which the agent is active, and a characteristic of the agent or the environment as nodes in a graph structure, and generating, as a scenario in the simulation, the graph structure in which a first node indicating the agent or a second node indicating the environment and a third node indicating the characteristic are connected.

### Supplementary Note 2

The data processing system according to supplementary note 1, in which the scenario generation unit generates the scenario by connecting the first node or the second node and the third node according to a predetermined prerequisite.

### Supplementary Note 3

The data processing system according to supplementary note 1, further including,

a feature amount collection unit for collecting a feature amount of the scenario generated by the scenario generation unit, and

a storage unit for storing the feature amount.

### Supplementary Note 4

The data processing system according to supplementary note 3, in which the feature amount collection unit collects statistical information of a connection frequency between the nodes and edges as a feature amount of the scenario.

### Supplementary Note 5

The data processing system according to supplementary note 3 or 4, further including a generated scenario evaluation unit for calculating similarity between the feature amount of the scenario generated by the scenario generation unit and the feature amount stored in the storage unit.

### Supplementary Note 6

The data processing system according to supplementary note 4 or 5, in which the scenario generation unit regards the statistical information as a probability distribution, and generates the scenario based on the statistical information stored in the storage unit.

### Supplementary Note 7

The data processing system according to supplementary note 6, in which the scenario generation unit generates the scenario including the probability distribution in which the similarity is larger than a predetermined value.

### Supplementary Note 8

The data processing system according to supplementary note 6, in which the scenario generation unit generates the scenario including the probability distribution in which the similarity is smaller than a predetermined value.

### Supplementary Note 9

The data processing system according to any one of supplementary notes 5 to 8, in which the generated scenario evaluation unit regards the statistical information as a probability distribution and calculates the similarity as a distance based on an optimal transport theory.

### Supplementary Note 10

The data processing system according to any one of supplementary notes 1 to 9, in which the characteristic of the agent includes a role of the agent.

### Supplementary Note 11

The data processing system according to any one of supplementary notes 1 to 9, in which the characteristic of the agent includes an attribute of the agent.

### Supplementary Note 12

The data processing system according to any one of supplementary notes 1 to 9, in which the characteristic of the agent includes a decision-making type of the agent.

### Supplementary Note 13

The data processing system according to supplementary note 3, in which the feature amount collection unit extracts the feature amount using a graph neural network.

### Supplementary Note 14

A data processing method including,

by a computer,

arranging an agent in a multi-agent simulation, an environment of the simulation in which the agent is active, and a characteristic of the agent or the environment as nodes in a graph structure, and

generating, as a scenario in the simulation, the graph structure in which a first node indicating the agent or a second node indicating the environment and a third node indicating the characteristic are connected.

### Supplementary Note 15

A program for causing a computer to execute,

a step of arranging an agent in a multi-agent simulation, an environment of the simulation in which the agent is active, and a characteristic of the agent or the environment as nodes in a graph structure, and

a step of generating, as a scenario in the simulation, the graph structure in which a first node indicating the agent or a second node indicating the environment and a third node indicating the characteristic are connected.

Some or all of the elements (e.g., configurations and functions) described in supplementary notes 2 to 13 subordinate to supplementary note 1 may also be subordinate to supplementary note 14 and supplementary note 15 due to the subordinate relationship similar to that of supplementary notes 2 to 13. Some or all of the elements described in any supplementary note may be applied to various types of hardware, software, recording means for recording software, systems, and methods.

1. A data processing system comprising:
at least one memory storing instructions, and
at least one processor configured to execute the instructions to;
arrange an agent in a multi-agent simulation, an environment of the simulation in which the agent is active, and a characteristic of the agent or the environment as nodes in a graph structure, and generate, as a scenario in the simulation, the graph structure in which a first node indicating the agent or a second node indicating the environment and a third node indicating the characteristic are connected.

2. The data processing system according to claim 1, wherein the at least one processor is further configured to execute the instructions to generate the scenario by connecting the first node or the second node and the third node according to a predetermined prerequisite.

3. The data processing system according to claim 1, wherein the at least one processor is further configured to execute the instructions to;
collect a feature amount of the scenario which is generated; and
store the feature amount.

4. The data processing system according to claim 3, wherein the at least one processor is further configured to execute the instructions to collect statistical information of a connection frequency between the nodes and edges as the feature amount of the scenario.

5. The data processing system according to claim 3, wherein the at least one processor is further configured to execute the instructions to calculate similarity between the feature amount of the scenario which is generated and the feature amount which is stored.

6. The data processing system according to claim 4, wherein the at least one processor is further configured to execute the instructions to regard the statistical information as a probability distribution, and generate the scenario based on the statistical information which is stored.

7. The data processing system according to claim 6, wherein the at least one processor is further configured to execute the instructions to generate the scenario including the probability distribution in which the similarity is larger than a predetermined value.

8. The data processing system according to claim 6, wherein the at least one processor is further configured to execute the instructions to generate the scenario including the probability distribution in which the similarity is smaller than a predetermined value.

9. The data processing system according to claim 5, wherein the at least one processor is further configured to execute the instructions to regard the statistical information as a probability distribution and calculates the similarity as a distance based on an optimal transport theory.

10. The data processing system according to claim 1, in which the characteristic of the agent includes a role of the agent.

11. The data processing system according to claim 1, in which the characteristic of the agent includes an attribute of the agent.

12. The data processing system according to claim 1, in which the characteristic of the agent includes a decision-making type of the agent.

13. The data processing system according to claim 3, wherein the at least one processor is further configured to execute the instructions to extract the feature amount using a graph neural network.

14. A data processing method comprising:
by a computer,
arranging an agent in a multi-agent simulation, an environment of the simulation in which the agent is active, and a characteristic of the agent or the environment as nodes in a graph structure; and
generating, as a scenario in the simulation, the graph structure in which a first node indicating the agent or a second node indicating the environment and a third node indicating the characteristic are connected.

15. A non-transitory computer-readable medium storing a program for causing a computer to execute:
a step of arranging an agent in a multi-agent simulation, an environment of the simulation in which the agent is active, and a characteristic of the agent or the environment as nodes in a graph structure; and
a step of generating, as a scenario in the simulation, the graph structure in which a first node indicating the agent or a second node indicating the environment and a third node indicating the characteristic are connected.
